(19) United States
(12) Patent Application Publication
(10) Pub. No.: US 2026/0343730 A1
(43) Pub. Date: Oct. 29, 2026

(54) FLEXIBLE PRINTED CIRCUIT BOARD, COF MODULE, AND ELECTRONIC DEVICE COMPRISING SAME

(71) Applicant: LG INNOTEK CO., LTD., Seoul (KR)

(72) Inventors: Sang Hun PARK, Seoul (KR); Ki Tae PARK, Seoul (KR)

(21) Appl. No.: 19/114,613

(22) PCT Filed: Sep. 18, 2023
(86) PCT No.: PCT/KR2023/014061

§ 371 Date: Mar. 24, 2025

(30) Foreign Application Priority Data
Sep. 23, 2022 (KR) 10-2022-0120947

(51) Int. Cl. H05K 1/02

(52) U.S. Cl. CPC H05K 1/0277; H05K 2201/10128

(57) ABSTRACT

A flexible circuit board according to an embodiment includes a substrate including a chip mounting region; and a circuit pattern disposed on the substrate, wherein the circuit pattern including a first circuit pattern, a second circuit pattern, and a third circuit pattern, wherein the first circuit pattern includes a first pad part disposed inside the chip mounting region, a second pad part disposed outside the chip mounting region, and a first wiring part connected to the first pad part and the second pad part, the second circuit pattern includes a third pad part disposed inside the chip mounting region, a fourth pad part disposed outside the chip mounting region, and a second wiring part connected to the third pad part and the fourth pad part, the third circuit pattern includes a third wiring part and a fifth pad part disposed inside the chip mounting region, and a width of the third wiring part is greater than a width of the fifth pad part.

### CROSS-REFERENCE TO RELATED APPLICATIONS

This application is the U.S. national stage application of International Patent Application No. PCT/KR 2023/014061, filed Sep. 18, 2023, which claims the benefit under 35 U.S.C. § 119 of Korean Application No. 10-2022-0120947, filed Sep. 23, 2022, the disclosures of each of which are incorporated herein by reference in their entirety.

### TECHNICAL FIELD

An embodiment relates to a flexible circuit board, a COF module and an electronic device including the same.

### BACKGROUND ART

Recently, various electronic products are becoming thinner. In addition, the electronic products are becoming smaller and lighter. Accordingly, it is required to mount a semiconductor chip in a narrow region of the electronic product at a high density.

A COF (Chip On Film) method uses a flexible substrate. Therefore, the COF method is applied to flexible displays. For example, the COF method can be applied to various wearable electronic devices. The COF method can form a fine pitch. Therefore, the COF method is applied to a high-resolution display.

The COF method is a method of mounting a semiconductor chip on a flexible circuit board in a form of a thin film. For example, the semiconductor chip may include an integrated circuit (IC) chip or a large scale integrated circuit (LSI) chip.

The chip is connected to a printed circuit board (PCB) and a display panel by a circuit pattern. For example, a pad part is disposed on one end and another end of the circuit pattern, respectively. One pad part is electrically connected to a terminal of the chip. In addition, the other pad part is connected to a terminal of the printed circuit board and the terminal of the display panel. Accordingly, the chip, the PCB, and the display panel are electrically connected through the COF. Accordingly, a signal is transmitted to the display panel by the circuit pattern.

A chip is mounted on the flexible circuit board. The chip has a multilayer structure. Each layer performs a corresponding role.

Recently, FLR (Film Level Route) technology has been applied. The FLR technology directly places a part of the multilayer structure and a circuit pattern connected to the part of the layers on the flexible circuit board. Since a routing pattern is disposed in a chip mounting region of the flexible circuit board, a size of the chip is reduced. Accordingly, a manufacturing cost of the chip is reduced.

A process of bonding the routing pattern and the chip is performed at high temperature and high pressure. Accordingly, stress may occur during the process. Accordingly, the stress may be transmitted to the routing pattern. Accordingly, a crack may occur in one region of the routing pattern. Therefore, the reliability of the COF module may be reduced.

Therefore, a flexible circuit board with a new structure capable of solving the problems, a COF module, and an electronic device including the same are required.

### DISCLOSURE

### Technical Problem An embodiment provides a flexible circuit board capable of securing reliability by inhibiting cracks in a routing pattern.

The embodiment provides a COF module having improved electrical characteristics.

### Technical Solution

A flexible circuit board according to an embodiment comprises a substrate including a chip mounting region; and a circuit pattern disposed on the substrate, wherein the circuit pattern includes a first circuit pattern, a second circuit pattern, and a third circuit pattern, wherein the first circuit pattern includes a first pad part disposed inside the chip mounting region, a second pad part disposed outside the chip mounting region, and a first wiring part connected to the first pad part and the second pad part, the second circuit pattern includes a third pad part disposed inside the chip mounting region, a fourth pad part disposed outside the chip mounting region, and a second wiring part connected to the third pad part and the fourth pad part, the third circuit pattern includes a third wiring part and a fifth pad part disposed inside the chip mounting region, and a width of the third wiring part is greater than a width of the fifth pad part.

### Advantageous Effects

The flexible circuit board according to the embodiment includes a third circuit pattern (routing pattern) disposed in a chip mounting region. When bonding the third circuit pattern and the chip, stress occurs. The third circuit pattern is formed in various sizes. Therefore, the third circuit pattern is inhibited from being damaged or deformed by the stress.

The stress can vary depending on location. Accordingly, a width of the wiring part of the third circuit pattern is formed in various sizes depending on location. Therefore, the third circuit pattern is inhibited from being damaged or deformed.

Accordingly, the flexible circuit board and the COF module have a small size. In addition, the flexible circuit board and the COF module have improved electrical characteristics.

### DESCRIPTION OF DRAWINGS

FIG. 1 is a top view of a COF module including a flexible circuit board according to an embodiment.

FIG. 2 is a drawing for explaining region A of FIG. 1.

FIG. 3 and FIG. 4 are cross-sectional views taken along region A-A′ of FIG. 2.

FIG. 5 is an enlarged view of region B of FIG. 2.

FIG. 6(a)-6(d) are drawings for explaining various shapes of region C of FIG. 3.

FIG. 7 is another drawing for explaining region A of FIG. 1.

FIG. 8 is an enlarged view of region D of FIG. 7.

FIG. 9 is another drawing for explaining region A of FIG. 1.

FIG. 10 is an enlarged view of region E of FIG. 9.

FIG. 11 is another drawing for explaining region A of FIG. 1.

FIG. 12 is an enlarged view of region F of FIG. 11.

FIG. 13 is another drawing for explaining region A of FIG. 1.

FIG. 14 is a cross-sectional view taken along region B-B′ of FIG. 13.

FIG. 15 is a top view of a COF module according to an embodiment.

FIG. 16 is a cross-sectional view showing a connection relationship of a COF module including a flexible circuit board according to an embodiment.

FIGS. 17 to 19 are drawings of electronic devices including a flexible circuit board according to an embodiment.

### MODE FOR INVENTION

Hereinafter, embodiments of the present disclosure will be described in detail with reference to the accompanying drawings. However, the spirit and scope of the present disclosure is not limited to a part of the embodiments described, and may be implemented in various other forms, and within the spirit and scope of the present disclosure, one or more of the elements of the embodiments may be selectively combined and redisposed.

In addition, unless expressly otherwise defined and described, the terms used in the embodiments of the present disclosure (including technical and scientific terms) may be construed the same meaning as commonly understood by one of ordinary skill in the art to which the present disclosure belongs, and the terms such as those defined in commonly used dictionaries may be interpreted as having a meaning that is consistent with their meaning in the context of the relevant art.

In addition, the terms used in the embodiments of the present disclosure are for describing the embodiments and are not intended to limit the present disclosure. In this specification, the singular forms may also include the plural forms unless specifically stated in the phrase, and may include at least one of all combinations that may be combined in A, B, and C when described in “at least one (or more) of A (and), B, and C”.

Further, in describing the elements of the embodiments of the present disclosure, the terms such as first, second, A, B, (a), and (b) may be used. These terms are only used to distinguish the elements from other elements, and the terms are not limited to the essence, order, or order of the elements.

In addition, when an element is described as being “connected”, “coupled”, or “contacted” to another element, it may include not only when the element is directly “connected” to, “coupled” to, or “contacted” to other elements, but also when the element is “connected”, “coupled”, or “contacted” by another element between the element and other elements.

In addition, when described as being formed or disposed “on (over)” or “under (below)” of each element, the “on (over)” or “under (below)” may include not only when two elements are directly connected to each other, but also when one or more other elements are formed or disposed between two elements.

Further, when expressed as “on (over)” or “under (below)”, it may include not only the upper direction but also the lower direction based on one element.

Hereinafter, a flexible circuit board, a COF module, and an electronic device including the same according to an embodiment will be described with reference to the drawings.

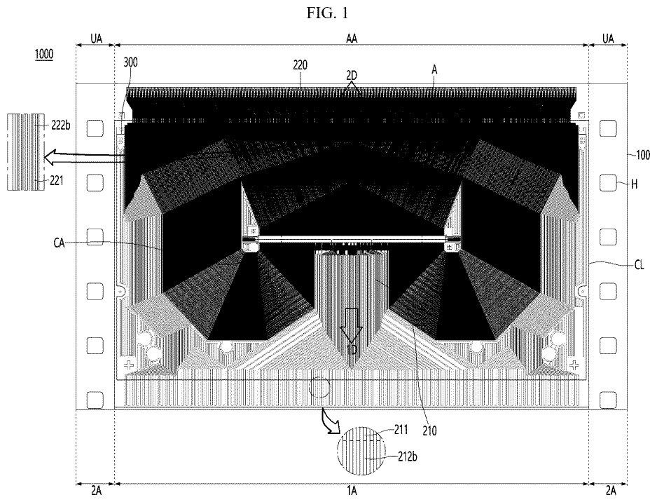

FIG. 1 is a top view of a flexible circuit board according to an embodiment.

Referring to FIG. 1, the flexible circuit board 1000 includes a substrate 100, a circuit pattern 200 disposed on the substrate 100, and a protective layer 300 disposed on the circuit pattern 200.

The substrate 100 may include a flexible substrate. For example, the substrate 100 may be a polyimide (PI) substrate. However, the embodiment is not limited thereto. The substrate 100 may include a polymer material such as polyethylene terephthalate (PET) or polyethylene naphthalate (PEN). Accordingly, the flexible circuit board is applied to various electronic devices including a curved display device. For example, the flexible circuit board may be applied to a wearable electronic device.

The substrate 100 has a thickness of 20 μm to 100 μm. For example, the substrate 100 may have a thickness of 25 μm to 50 μm. For example, the substrate 100 may have a thickness of 30 um to 40 μm. If the thickness of the substrate 100 exceeds 100 μm, the thickness of the flexible circuit board may increase. Accordingly, the flexible characteristic of the flexible circuit board decreases. In addition, if the thickness of the substrate 100 is less than 20 μm, the substrate 100 may be damaged when a chip is mounted on the flexible circuit board.

The substrate 100 includes an effective region UA and a non-effective region UA. For example, the effective region AA may be a central region of the substrate 100. In addition, the non-effective region UA may be an edge region of the substrate 100.

The effective region AA includes a chip mounting region CA. The chip mounting region CA is a region where a chip connected to the circuit pattern is mounted. The protective layer 300 is not disposed in the chip mounting region CA. Accordingly, a pad part of the circuit pattern disposed in the chip mounting region CA is exposed. Accordingly, the pad part of the circuit pattern and a terminal part of the chip are connected.

A plurality of circuit patterns 210, 220, and 230 are disposed on the effective region AA. In detail, the plurality of circuit patterns are spaced apart from each other. In addition, the plurality of circuit patterns extend in a plurality of directions.

The effective region AA is a region actually used in the flexible circuit board 1000. That is, when the flexible circuit board comes into contact with another panel, etc., the effective region AA is a region in contact with the panel.

The circuit pattern is not disposed in the non-effective region UA.

The non-effective region UA includes a plurality of holes. In detail, the non-effective region UA includes a plurality of sprocket holes (H). The flexible circuit board is rolled or unrolled in a roll-to-roll manner by the sprocket holes (H).

The non-effective region UA is a region that is not actually used in the flexible circuit board 1000. When the flexible circuit board is in contact with another panel, etc., the non-effective region UA is removed.

In detail, the flexible circuit board 1000 includes a cutting line CL that is a boundary between the non-effective region UA and the effective region AA. The COF module is manufactured by cutting the cutting line CL.

The circuit pattern includes a wiring part and a pad part. In addition, a plurality of circuit patterns are disposed in the effective region AA. The circuit pattern includes a first circuit pattern 210, a second circuit pattern 220, and a third circuit pattern 230.

In detail, the first circuit pattern 210 and the second circuit pattern 220 are disposed in an inner region of the chip mounting region CA and an outer region of the chip mounting region CA.

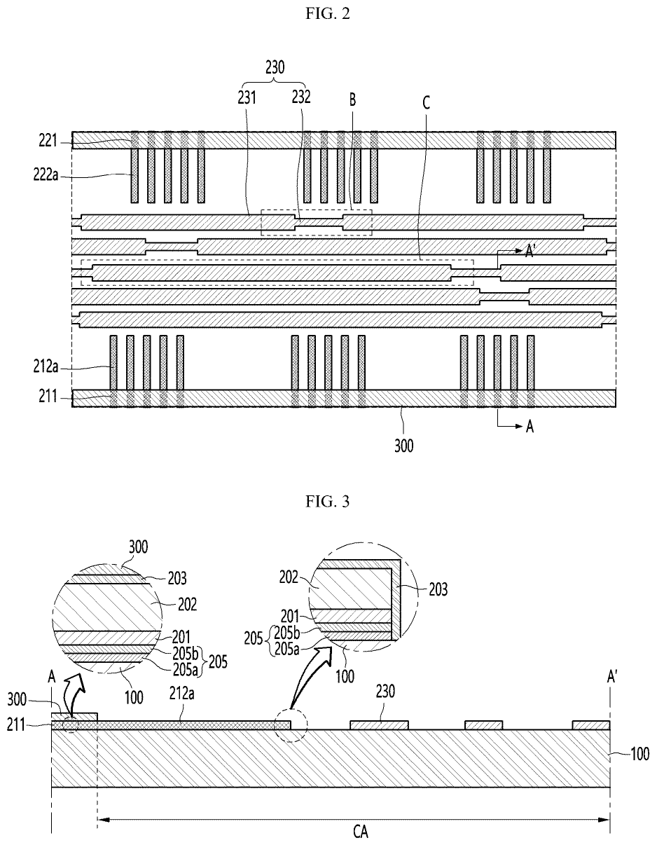

In addition, the third circuit pattern 230 is disposed in the inner region of the chip mounting region CA. Referring to FIG. 1 and FIG. 2, the first circuit pattern 210 includes a first wiring part 211, a first pad part 212a, and a second pad part 212b. The first pad part 212a is disposed inside the chip mounting region CA. The second pad part 212b is disposed outside the chip mounting region CA. The first wiring part 211 is disposed between the first pad part 212a and the second pad part 212b. The first pad part 212a and the second pad part 212b are connected by the first wiring part 211.

The first wiring part 211, the first pad part 212a, and the second pad part 212b may be formed integrally.

The first wiring part 211 extends in a first direction based on the chip mounting region CA.

The first pad part 212a is electrically connected to the chip. The second pad part 212b is electrically connected to a printed circuit board. The first wiring part 211 transmits a signal between the chip and the printed circuit board.

A protective layer 300 is disposed on the first circuit pattern 210. The protective layer 300 is disposed on the first wiring part 211. The protective layer 300 surrounds the first wiring part 211. In addition, the protective layer 300 is not disposed on the first pad part 212a and the second pad part 212b. Therefore, the first pad part 212a and the second pad part 212b are exposed to an outside.

The second circuit pattern 220 includes a second wiring part 221, a third pad part 222a, and a fourth pad part 222b. The third pad part 222a is disposed inside the chip mounting region CA. The fourth pad part 222b is disposed outside the chip mounting region CA. The second wiring part 221 is disposed between the third pad part 222a and the fourth pad part 222b. The third pad part 222a and the fourth pad part 222b are connected by the second wiring part 221.

The second wiring part 221, the third pad part 222a, and the fourth pad part 222b may be formed integrally.

The second wiring part 221 extends in a second direction based on the chip mounting region CA. The second direction is opposite to the first direction.

The third pad part 222a is electrically connected to the chip. In addition, the fourth pad part 222b is electrically connected to the display panel. In addition, the second wiring part 221 transmits a signal between the chip and the display panel.

The protective layer 300 is disposed on the second circuit pattern 220. The protective layer 300 is disposed on the second wiring part 221. The protective layer 300 surrounds the second wiring part 221. In addition, the protective layer 300 is not disposed on the third pad part 222a and the fourth pad part 222b. Therefore, the third pad part 222a and the fourth pad part 222b can be exposed to the outside.

The third circuit pattern 230 includes a third wiring part 231 and a plurality of fifth pad parts 232. The third wiring part 231 and the fifth pad part 232 are disposed inside the chip mounting region CA.

The third circuit pattern 230 is connected to the chip. The fifth pad parts 232 are electrically connected to the chip. The third circuit pattern 230 includes a plurality of third circuit patterns. Each of the third circuit patterns 230 includes at least one fifth pad part. Each of the fifth pad parts is electrically connected to the chip.

The third circuit pattern 230 may be a routing pattern. The third circuit pattern 230 may be an FLR (Film Level Route) pattern. The routing pattern functions as a chip. Therefore, some of layers of the chip are redisposed with the routing pattern.

The third circuit pattern 230 is connected to the chip by the fifth pad part. Therefore, the signal of the first circuit pattern 210 is transmitted to the third circuit pattern 230. In addition, the signal is transmitted to the chip and the second circuit pattern 220 by the third circuit pattern 230. Therefore, the signal is transmitted to the display panel.

At least one of the first circuit pattern 210, the second circuit pattern 220, and the third circuit pattern 230 may include a metal material having high electrical conductivity. In detail, at least one of the first circuit pattern 210, the second circuit pattern 220, and the third circuit pattern 230 may include copper (Cu).

However, the embodiment is not limited thereto. At least one of the first circuit pattern 210, the second circuit pattern 220, and the third circuit pattern 230 may include at least one metal among copper (Cu), aluminum (Al), chromium (Cr), nickel (Ni), silver (Ag), molybdenum (Mo), gold (Au), titanium (Ti), and alloys thereof.

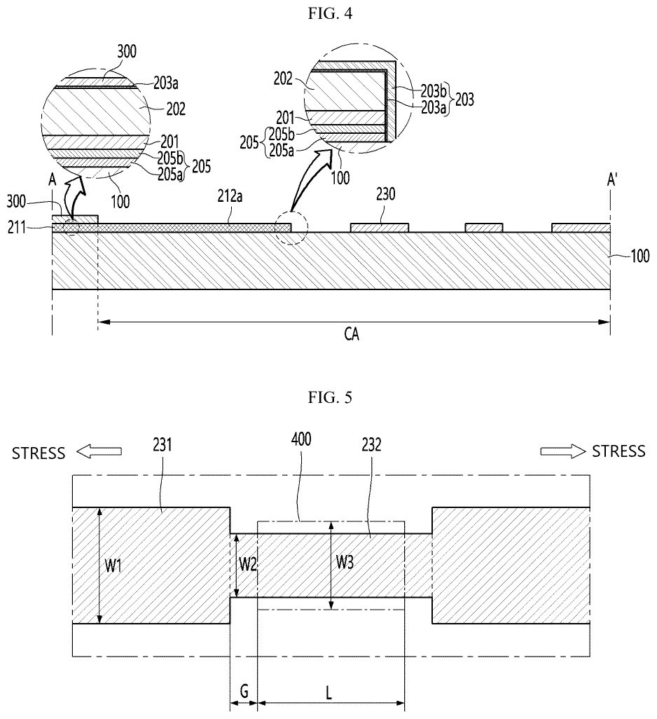

A layer structure of the circuit pattern is described with reference to FIGS. 3 and 4. A description of the layer structure described in FIGS. 3 and 4 is applied to at least one of the first circuit pattern 210, the second circuit pattern 220, and the third circuit pattern 230. Hereinafter, the first circuit pattern will be described for convenience of explanation.

Referring to FIG. 3, the first circuit pattern 210 is formed of multiple layers. In detail, the first wiring part 211 and the first pad part 212a include a first metal layer 201 and a second metal layer 202. In addition, the second pad part 212b also includes the first metal layer 201 and the second metal layer 202.

The first metal layer 201 is a seed layer of the first circuit pattern 210. The first metal layer 201 may include copper (Cu). The first metal layer 201 is formed by electroless plating.

The second metal layer 202 is a plating layer. The second metal layer 202 is formed by electrolytic plating. The second metal layer 202 is formed using the first metal layer 201 as a seed layer.

A thickness of the first metal layer 201 is smaller than a thickness of the second metal layer 202. For example, the thickness of the first metal layer 201 may be 0.7 μm to 2 μm. The thickness of the second metal layer 202 may be 10 μm to 25 μm.

The first metal layer 201 and the second metal layer 202 may include a same metal material. For example, the first metal layer 201 and the second metal layer 202 may include copper (Cu).

In addition, a bonding layer 203 is disposed on the second metal layer 201. The bonding layer 203 is disposed on a side surface of the first metal layer 201, a side surface of the second metal layer 202, and an upper surface of the second metal layer 202. The bonding layer 203 surrounds the first metal layer 201 and the second metal layer 202.

The bonding layer 203 includes a metal. For example, the bonding layer 203 may include tin (Sn).

A thickness of the bonding layer 203 may be 0.3 μm to 0.7 μm.

A content of tin may increase as it extends from a lower surface of the bonding layer 203 toward an upper surface of the bonding layer 203. In addition, a content of copper may decrease as it extends from the lower surface toward the upper surface. The lower surface is a surface where the bonding layer 203 and the second metal layer 202 come into contact.

Accordingly, only pure tin can remain in a thickness range of 0.1 um to 0.3 um from the upper surface of the bonding layer 203.

A terminal of the chip, a pad part of the printed circuit board, and a pad part of the display panel can be easily bonded by heat and pressure by the bonding layer 203. That is, when heat and pressure are applied to the pad part, the upper surface of the bonding layer where pure tin remains is melted. Accordingly, the chip, the printed circuit board, and the display panel are easily bonded.

A thickness of the first circuit pattern 210 may be 2 μm to 25 μm. For example, the thickness of the first circuit pattern 210 may be 5 μm to 20 μm. For example, the thickness of the first circuit pattern 210 may be 7 μm to 15 μm.

Flash etching is performed to separate the first circuit patterns during a manufacturing process. Accordingly, the first metal layer 201 is etched. Accordingly, the first circuit pattern 210 finally manufactured is smaller than a sum of the thicknesses of the first metal layer 201, the second metal layer 202, and the bonding layer 203 formed during the manufacturing process.

If the thickness of the first circuit pattern 210 is less than 2 μm, a resistance of the first circuit pattern 210 may increase. If the thickness of the first circuit pattern 210 exceeds 25 μm, it may be difficult to form a fine pattern.

A buffer layer 205 may be disposed between the substrate 100 and the first circuit pattern 210. An adhesion between the substrate 100 and the first circuit pattern 210 is improved by the buffer layer 205.

The buffer layer 205 may be formed of a plurality of layers. The buffer layer 205 may include a first buffer layer 205a and a second buffer layer 205b on the first buffer layer 205a. The first buffer layer 205a is in contact with the substrate 100. The second buffer layer 205b is in contact with the first circuit pattern 210.

The first buffer layer 205a may include a material having good adhesion to the substrate 100. For example, the first buffer layer 205a may include nickel (Ni). In addition, the second buffer layer 205b may include a material having good adhesion to the first circuit pattern 210. For example, the second buffer layer 205b may include chromium (Cr).

The buffer layer 205 may have a thin film thickness in nanometer units. For example, the buffer layer 205 may have a thickness of 20 nm or less.

An adhesion between the substrate 100 and the first circuit pattern 210 is increased by the buffer layer 205.

Referring to FIG. 4, the bonding layer 203 includes a plurality of bonding layers. The bonding layer 203 may include a first bonding layer 203a and a second bonding layer 203b.

The first bonding layer 203a is disposed on the first wiring part 211 and the first pad part 212a. In addition, the first bonding layer 203a is also disposed on the second pad part 212b. That is, the first bonding layer 203a is disposed on the first circuit pattern 210.

In addition, the second bonding layer 203b is disposed only on the first pad part 212a and the second pad part 212b.

The first bonding layer 203a and the second bonding layer 203b include a metal. In detail, the first bonding layer 203a and the second bonding layer 203b may include tin (Sn).

The first bonding layer 203a and the second bonding layer 203b have different thicknesses. The thickness of the second bonding layer 203b is greater than the thickness of the first bonding layer 203a.

For example, the first bonding layer 203a may have a thin film thickness of 0.02 μm to 0.06 μm. In addition, the second bonding layer 203b may have a thickness of 0.2 μm to 0.6 μm.

If the bonding layer between the protective layer 300 and the first wiring part 211 becomes thick, bending characteristics of the flexible circuit board decrease. That is, when the flexible circuit board is bent, a crack may occur. Accordingly, the first bonding layer 231 between the protective layer 300 and the first wiring part 211 is formed with a thin thickness. Accordingly, the bending characteristics of the flexible circuit board are improved.

A tin content may increase while extending from a lower surface to the upper surface of the second bonding layer 203b. In addition, a copper content may decrease while extending from the lower surface to the upper surface. The lower surface is the surface where the second bonding layer 203b and the first bonding layer 203a come into contact.

Accordingly, only pure tin can remain in a thickness range of 0.1 μm to 0.3 μm from the upper surface of the second bonding layer 203b.

The terminal of the chip, the pad part of the printed circuit board, and the pad part of the display panel can be easily bonded by heat and pressure by the second bonding layer 203b. That is, when heat and pressure are applied to the pad part, the upper surface of the bonding layer where pure tin remains is melted. Accordingly, the chip, the printed circuit board, and the display panel are easily bonded.

The protective layer 300 is disposed on the wiring part of the first circuit pattern 210 and the second circuit pattern 220. The protective layer 300 surrounds the first wiring part 211 and the second wiring part 221. The protective layer 300 is disposed in a region excluding the first pad part, the second pad part, the third pad part, and the fourth pad part.

The protective layer 300 may include a solder paste. For example, the solder paste may include a thermosetting resin, a thermoplastic resin, a filler, a curing agent, or a curing accelerator.

In the above description, the first circuit pattern 210 and the second circuit pattern 220 are disposed on a same surface of the substrate 100, but the embodiment is not limited thereto.

For example, the first circuit pattern 210 and the second circuit pattern 220 may be disposed on different surfaces of the substrate 100. For example, the first circuit pattern 210 may be disposed on one surface of the substrate 100. In addition, the second circuit pattern 220 may be disposed on the other surface of the substrate 100.

Accordingly, the display panel is connected to the chip on one surface of the substrate 100. In addition, the printed circuit board is connected to the chip on the other surface of the substrate 100.

The third circuit pattern 230 is disposed inside the chip mounting region CA.

The chip and the pad part of the first circuit pattern, the second circuit pattern, and the third circuit pattern are bonded in a high temperature and high pressure environment. Therefore, when bonding the pad part of the chip and the circuit pattern, stress may occur.

A protective layer is disposed on the wiring part of the first circuit pattern and the second circuit pattern. Accordingly, even if stress is transmitted to the wiring part of the first circuit pattern and the second circuit pattern, deformation or cracking of the first circuit pattern and the second circuit pattern can be inhibited.

However, a protective layer is not disposed on the third circuit pattern. Accordingly, if the stress is transmitted to the wiring part of the third circuit pattern, deformation or cracking of the third circuit pattern may occur.

Therefore, a shape of the third circuit pattern may change. Accordingly, adjacent third circuit patterns may be short-circuited. Alternatively, a crack may occur in one region of the third circuit pattern. Accordingly, the electrical characteristics of the COF module may be reduced.

Hereinafter, a flexible circuit board and a COF module capable of solving the above-described problems will be described.

Referring to FIGS. 2, 5, and 6(a)-6(d), the third circuit pattern 230 includes regions having different sizes. In detail, the third circuit pattern 230 may include regions having different widths. In detail, a width w1 of the third wiring part 231 is different from a width w2 of the fifth pad part 232.

The width w1 of the third wiring part 231 is greater than the width w2 of the fifth pad part 232. The width w1 of the third wiring part 231 is a maximum width of the third wiring part. The width w2 of the fifth pad part 232 is a maximum width of the fifth pad part 232.

A terminal part 400 of the chip is disposed on the fifth pad part 232. Since the width w2 of the fifth pad part 232 is smaller than the width w1 of the third wiring part 231, the third circuit pattern 230 can be inhibited from increasing in spacing due to the terminal part 400. Accordingly, a size of the flexible circuit board can be inhibited from increasing. In addition, a number of third circuit patterns disposed on the chip mounting region CA can be increased.

The width w1 of the third wiring part 231 is greater than the width w2 of the fifth pad part 232. Therefore, when bonding the fifth pad part 232 and the terminal part 400, the third wiring part 231 can be inhibited from being damaged. In detail, the fifth pad part 232 and the terminal part 400 are bonded at high temperature and high pressure. Therefore, stress may occur during the bonding process. The stress moves toward the third wiring part 231.

The width w1 of the third wiring part 231 is greater than the width w2 of the fifth pad part 232. Therefore, a strength of the third wiring part 231 increases. In detail, since the width w1 of the third wiring part 231 increases, an area of the third wiring part 231 increases. Accordingly, a size of the stress per unit area of the third wiring part 231 decreases. Therefore, a shape of the third wiring part 231 can be inhibited from changing due to the stress. In addition, cracks in the third wiring part 231 can be inhibited.

For example, the width w1 of the third wiring part 231 can be three times or less than the width w2 of the fifth pad part 232. In detail, the width w1 of the third wiring part 231 can be greater than one and less than three times the width w2 of the fifth pad part 232. In more detail, the width w1 of the third wiring part 231 may be 1.5 to 3 times or 2 to 2.5 times the width w2 of the fifth pad part 232.

If the width w1 of the third wiring part 231 exceeds 3 times the width w2 of the fifth pad part 232, a spacing between the third circuit patterns becomes narrower. Accordingly, adjacent third circuit patterns may be short-circuited. In addition, a number of third circuit patterns disposed in the chip mounting region decreases. Accordingly, the layer of the chip increases, and a size of the chip increases.

In addition, the width w1 of the third wiring part 231 may be greater than or equal to a distance G between the third wiring part 231 and the terminal part 400. In addition, the width w1 of the third wiring part 231 may be less than or equal to a length L of the terminal part 400. In addition, the width w1 of the third wiring part 231 may be greater or smaller than a width w3 of the terminal part 400.

For example, the width w1 of the third wiring part 231 may be 20 μm to 30 μm. In addition, the width w2 of the fifth pad part 232 may be 9 μm to 20 μm. In addition, the distance G between the third wiring part 231 and the terminal part 400 may be 10 μm to 30 μm. In addition, the length L of the terminal part 400 may be 30 μm to 50 μm. In addition, the width w3 of the terminal part 400 may be 15 μm to 50 μm.

In the drawing, the third wiring part 231 is illustrated as having a square shape. However, the embodiment is not limited thereto.

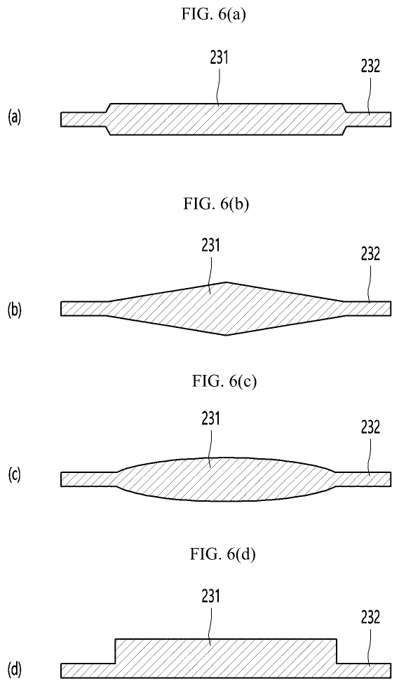

Referring to FIG. 6(a)-6(d), the third wiring part 231 may be formed in various shapes. For example, referring to FIG. 6(a), the third wiring part 231 may be formed in a hexagonal shape. Alternatively, referring to FIG. 6(b), the width of the third wiring part 231 may decrease from a center to a periphery. Alternatively, referring to FIG. 6(c), the third wiring part 231 may include a curved surface. Accordingly, it is possible to inhibit the width of the pattern from changing abruptly in a boundary region between the third wiring part 231 and the fifth pad part 232. By this, it is possible to inhibit stress from being concentrated in the boundary region between the fifth pad part 232 and the third wiring part 231. Therefore, cracks in the boundary region between the fifth pad part 232 and the third wiring part 231 can be inhibited.

Alternatively, referring to FIG. 6(d), the third wiring part 231 can protrude in one direction. Accordingly, a spacing of the third circuit pattern can be easily controlled. In detail, the spacing between adjacent third circuit patterns can be narrowed by the third wiring part having a large width. Therefore, a position of the third wiring part can be controlled according to a space of the chip mounting region. Therefore, a spacing of the third circuit pattern can be easily controlled.

The flexible circuit board according to the embodiment forms the width of the third circuit pattern differently for each region. In detail, the width of the fifth pad part is formed smaller than that of the wiring part. Accordingly, it is possible to inhibit the terminal part of the chip disposed on one fifth pad part from interfering with another fifth pad part. In addition, it is possible to inhibit the spacing of the third circuit pattern from increasing in order to inhibit interference of the terminal part.

In addition, the width of the wiring part of the third circuit pattern is greater than the fifth pad part. Accordingly, it is possible to inhibit the wiring part of the third circuit pattern from being deformed or cracked due to the stress.

In addition, the width of the wiring part of the third circuit pattern is increased. Accordingly, heat can be effectively dissipated when the chip is mounted. Alternatively, heat generated after the chip is mounted can be effectively dissipated. That is, the wiring part of the third circuit pattern can be a heat dissipation pattern. Accordingly, an internal temperature of the flexible circuit board or COF module decreases.

Accordingly, the flexible circuit board has a small size. In addition, the flexible circuit board has improved electrical characteristics. In addition, heat inside the flexible circuit board is effectively dissipated.

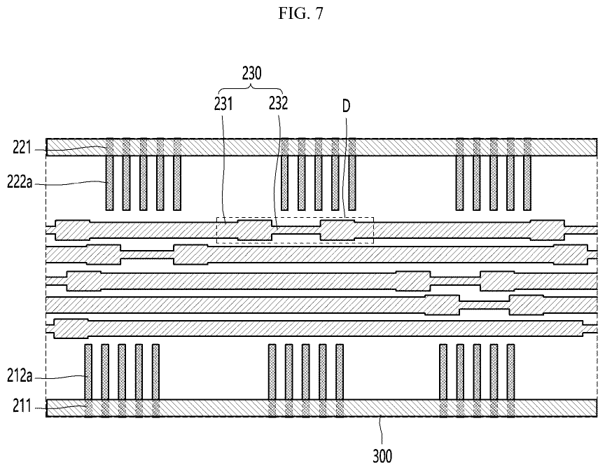

Hereinafter, a flexible circuit board according to another embodiment will be described with reference to FIGS. 7 to 14.

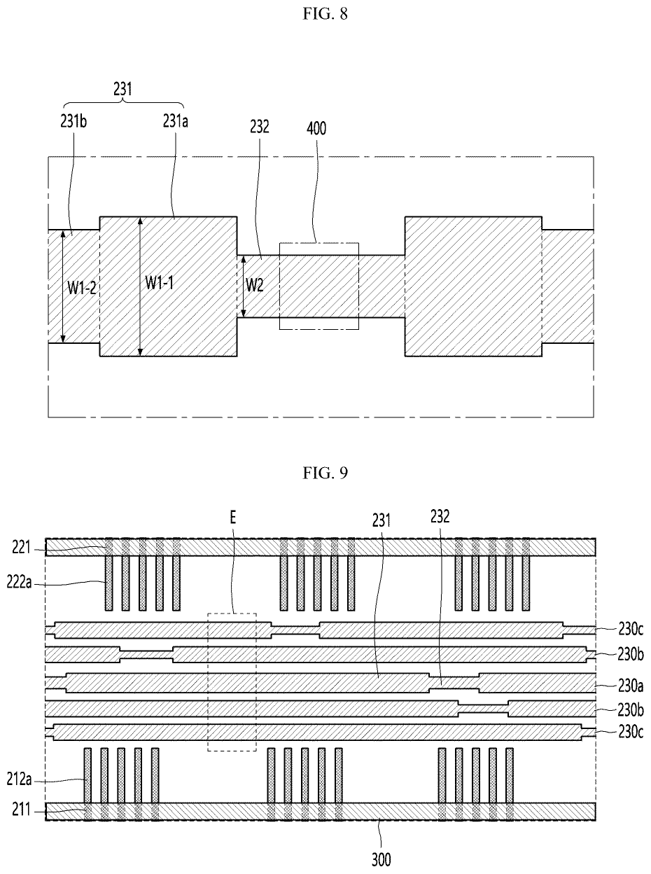

Referring to FIGS. 7 and 8, the third wiring part 231 includes regions having different widths. For example, the third wiring part 231 may include a third-first wiring part 231a and a third-second wiring part 231b.

The third-first wiring part 231a is adjacent to the fifth pad part 232. In detail, the third-first wiring part 231a is connected to the fifth pad part 232. In addition, the third-second wiring part 231b is connected to the third-first wiring part 231a. In detail, the third-first wiring part 231a is connected to an end of the third-second wiring part 231b. That is, the third-first wiring part 231a is disposed between the fifth pad part 232 and the third-second wiring part 231b.

When the fifth pad part 232 and the terminal part 400 are bonded, stress may occur. A width w1-1 of the third-first wiring part 231a and a width w-2 of the third-second wiring part 231b may be greater than the width w2 of the fifth pad part 232. Accordingly, the unit area of the third wiring part increases. Accordingly, shapes of the third-first wiring part 231a and the third-second wiring part 231b are inhibited from being deformed or cracks from being formed due to the stress.

In addition, the width w1-1 of the third-first wiring part 231a and the width w1-2 of the third-second wiring part 231b may be different. Specifically, the width w1-1 of the third-first wiring part 231a is greater than the width w1-2 of the third-second wiring part 231b. That is, the width of the third wiring part 231 adjacent to the fifth pad part 232 is greater than the width of the third wiring part 231 distant from the fifth pad part 232.

The stress may be largest in a region adjacent to the fifth pad part 232. Accordingly, considering the distribution of stress transmitted to the third wiring part 231, the width w1-1 of the third-first wiring part 231a is formed greater than the width w1-2 of the third-second wiring part 231b. Therefore, when bonding the third circuit pattern and the chip, the third circuit pattern can be inhibited from being deformed or cracked.

Therefore, the flexible circuit board has improved electrical characteristics.

Referring to FIGS. 9 to 12, a plurality of third circuit patterns are disposed in the chip mounting region CA. For example, the third circuit pattern may include a third-first circuit pattern 230a, a third-second circuit pattern 230b, and a third-third circuit pattern 230c.

The third-first circuit pattern 230a and the third-second circuit pattern 230b are adjacent. In addition, the third-second circuit pattern 230b and the third-third circuit pattern 230c are adjacent. For example, the third-first circuit pattern 230a may be disposed on a central portion of the chip mounting region CA. In addition, the third-second circuit pattern 230b and the third-third circuit pattern 230c may be disposed between a central portion and an outer portion of the chip mounting region CA.

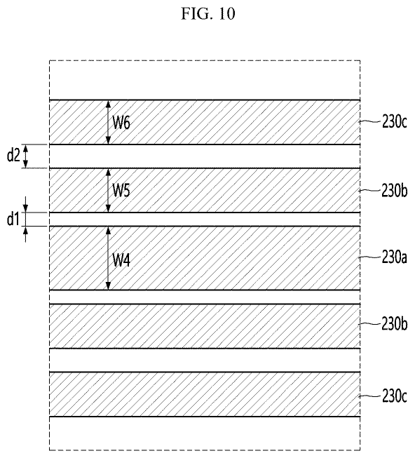

Referring to FIGS. 9 and 10, among the third-first circuit pattern 230a, the third-second circuit pattern 230b, and the third-third circuit pattern 230c, a width of a wiring part of one circuit pattern may be different from a width of a wiring part of another circuit pattern. For example, a width w4 of a wiring part of the third-first circuit pattern 230a may be greater than a width w5 of a wiring part of the third-second circuit pattern 230b and a width w5 of a wiring part of the third-third circuit pattern 230c. Accordingly, the width of the wiring part of the circuit pattern disposed in the central portion of the chip mounting region CA may be greater.

In addition, the third-first circuit pattern 230a, the third-second circuit pattern 230b, and the third-third circuit pattern 230c may be disposed at different spacings. For example, a first spacing dl between the third-first circuit pattern 230a and the third-second circuit pattern 230b and a second spacing d2 between the third-second circuit pattern 230b and the third-third circuit pattern 230c may be different from each other. For example, the first spacing d1 may be smaller than the second spacing d2.

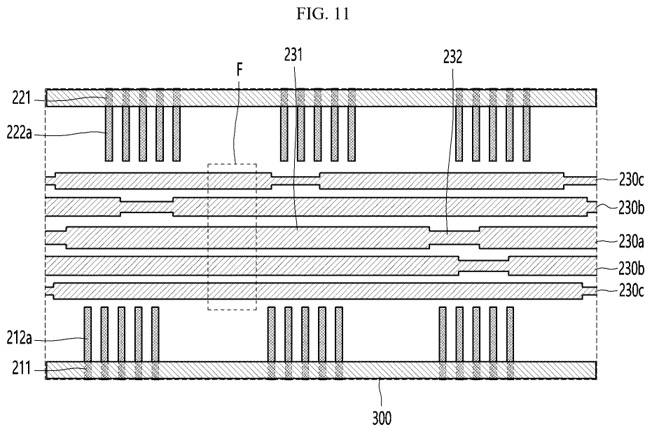

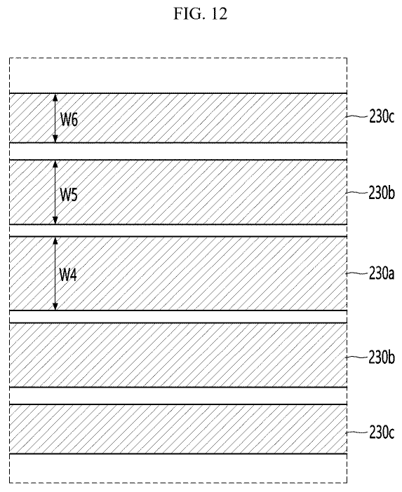

Alternatively, referring to FIG. 11 and FIG. 12, the widths of the circuit patterns of the third-first circuit pattern 230a, the third-second circuit pattern 230b, and the third-third circuit pattern 230c may be different. In detail, the width w4 of the wiring part of the third-first circuit pattern 230a may be greater than the width w5 of the wiring part of the third-second circuit pattern 230b and the width w5 of the wiring part of the third-third circuit pattern 230c. In addition, the width w5 of the wiring part of the third-second circuit pattern 230b may be greater than the width w5 of the wiring part of the third-third circuit pattern 230c. Accordingly, the width of the wiring part of the third-first circuit pattern disposed in the central portion of the chip mounting region is the largest. In addition, the width of the wiring part of the third circuit pattern becomes smaller as it moves away from the central portion.

That is, widths of the wiring parts of the plurality of third circuit patterns may become smaller as they extend to the outer region of the chip mounting region. Alternatively, spacings of the wiring parts of the plurality of third circuit patterns may be increased while extending to the outer region of the chip mounting region.

The pad parts of the first circuit pattern, the second circuit pattern, and the third circuit pattern and the terminal part of the chip may be bonded at high temperature and high pressure. At this time, the temperature and pressure of the central region of the chip mounting region CA may be greater than those of other regions. Accordingly, the third circuit pattern disposed in the central portion of the chip mounting region may be subjected to greater stress than the third circuit patterns disposed in other positions.

Therefore, the width of the wiring part of the third circuit pattern disposed in the central portion of the chip mounting region is greater than the width of the wiring part of the other third circuit patterns. Alternatively, the width of the wiring part of the third circuit pattern becomes smaller while extending from the central portion of the chip mounting region toward the outer portion.

Accordingly, even if different stresses occur at each position, deformation and cracking of the third circuit pattern can be effectively inhibited.

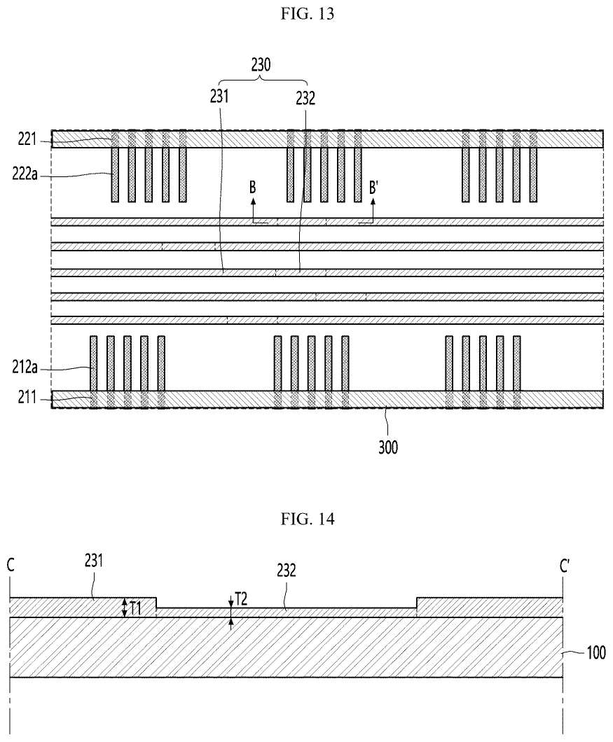

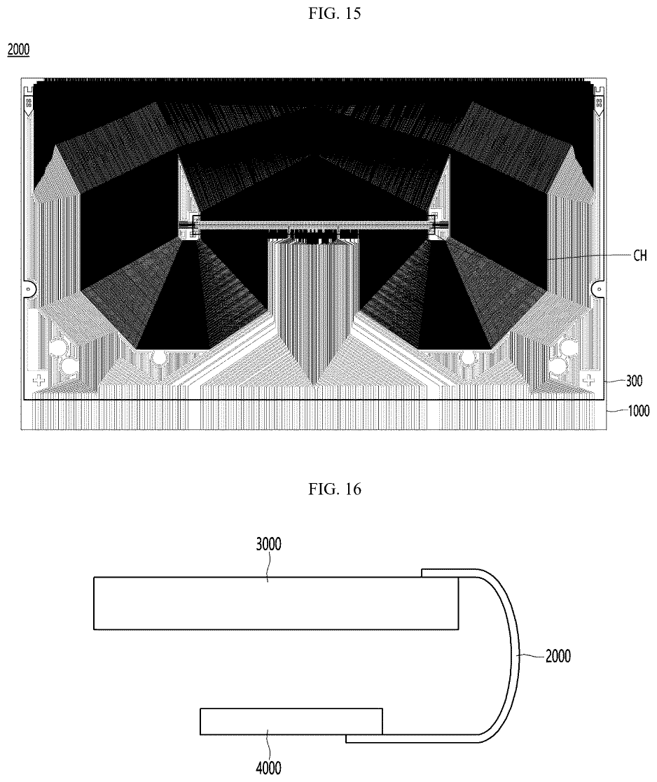

Referring to FIG. 13 and FIG. 14, the width of the third wiring part 231 and the width of the fifth pad part 232 may be the same or similar. In addition, a thickness T1 of the third wiring part and a thickness T2 of the fifth pad part 232 may be different.

In detail, a thickness T1 of the third wiring part may be greater than a thickness T2 of the fifth pad part 232.

Since the thickness T1 of the third wiring part is greater than the thickness T2 of the fifth pad part 232, the third wiring part 231 can be inhibited from being damaged when bonding the fifth pad part 232 and the terminal part 400. In detail, by increasing the thickness T1 of the third wiring part, the strength of the third wiring part 231 can be increased. Accordingly, it is possible to inhibit the shape of the third wiring part 231 from being changed or a crack from being formed due to stress generated during bonding of the chip and the fifth pad part.

In addition, the width of the third wiring part and the width of the fifth pad part 232 may be the same or similar. Accordingly, the gap between the third circuit patterns is widened. Accordingly, it is possible to inhibit the third circuit pattern from being short-circuited. Alternatively, the size of the chip mounting region can be reduced. Accordingly, a small-sized flexible circuit board can be manufactured. Alternatively, the number of third circuit patterns disposed in the chip mounting region can be increased.

FIG. 15 is a drawing showing a top view of a COF module according to an embodiment.

Referring to FIG. 15, a COF module according to an embodiment includes a flexible circuit board as described above. In addition, the COF module may include a chip CH disposed on the chip mounting region CA.

In addition, the flexible circuit board 1000 may include a protective layer 300 as described above.

Meanwhile, the COF module is manufactured by cutting the flexible circuit board 1000 and mounting the chip CH. In detail, the flexible circuit board 1000 is cut along the cutting line CL. Subsequently, a driving chip is mounted on the chip mounting region.

The COF module is disposed between a display panel and a printed circuit board and can transmit a signal.

Referring to FIG. 16, one end of the COF module 2000 according to the embodiment is connected to the display panel 3000. In addition, the other end of the COF module 2000 is connected to the printed circuit board 4000.

The COF module 2000 includes a flexible substrate. Therefore, it can have a rigid form or a bent form between the display panel 3000 and the printed circuit board 4000.

The COF module 2000 can connect the display panel 3000 and the printed circuit board 4000 in a bent form. Therefore, a thickness of the electronic device is reduced, and the degree of freedom of design is improved. In addition, since the COF module 2000 includes the flexible substrate, the wiring is not broken even in a bent form. Therefore, the reliability of the electronic device is improved.

The COF module can be applied to various electronic devices.

For example, referring to FIG. 17, the COF module is applied to a flexible touch window that can be bent. Therefore, the user can bend the touch device by a hand.

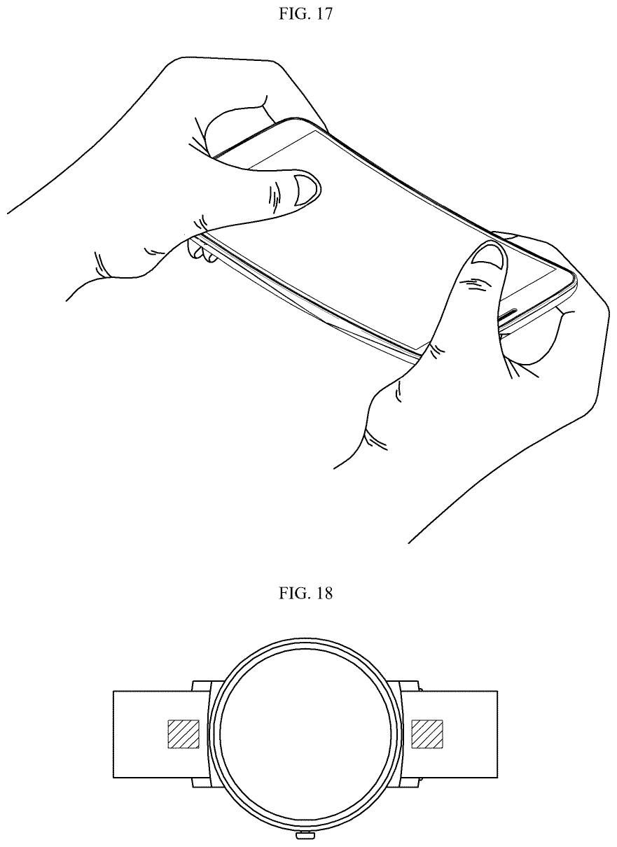

Referring to FIG. 18, the COF module is applied to various wearable touch devices including a curved display. Therefore, the electronic device can be slimmed down or made lightweight.

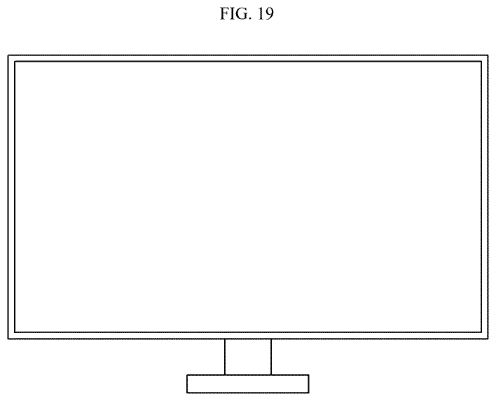

Referring to FIG. 19, the COF module is applied to various electronic devices having displays such as TVs, monitors, and laptops. The COF module can also be used in electronic devices having a curved display. is applied.

The characteristics, structures, effects, and the like described in the above-described embodiments are included in at least one embodiment of the present invention, but are not limited to only one embodiment. Furthermore, the characteristic, structure, and effect illustrated in each embodiment may be combined or modified for other embodiments by a person skilled in the art. Accordingly, it is to be understood that such combination and modification are included in the scope of the present invention.

In addition, embodiments are mostly described above, but the embodiments are merely examples and do not limit the present invention, and a person skilled in the art may appreciate that several variations and applications not presented above may be made without departing from the essential characteristic of embodiments. For example, each component specifically represented in the embodiments may be varied. In addition, it should be construed that differences related to such a variation and such an application are included in the scope of the present invention defined in the following claims.

1. A flexible circuit board comprising:
a substrate;
a circuit pattern disposed on the substrate; and
a protective layer disposed on the substrate and the circuit pattern, and including an opening passing through upper and lower surfaces,
wherein the circuit pattern includes a routing pattern, disposed in the opening,
wherein the routing pattern includes a plurality of routing pads disposed in the opening, and a routing wire disposed in the opening and directly connecting between the plurality of routing pads. and
wherein a width of the routing wire is greater than a width of each routing pad.

2. The flexible circuit board of claim 1, wherein the width of the routing wire is greater than 1 times and less than 3 times the width each routing pad.

3. The flexible circuit board of claim 1, wherein the
routing wire includes a first portion directly connected to each routing pad, and a second portion directly connected to the first portion, and
wherein the first portion and the second portion have different widths.

4. The flexible circuit board of claim 3, wherein the width of the first portion of the routing wire is greater than the width of second portion of the routing wire.

5. The flexible circuit board of claim 1, wherein the routing pattern includes first to third routing patterns spaced apart from each other,
wherein the first routing pattern is disposed in a central portion of the opening,
wherein the second routing pattern and the third routing pattern are disposed between the central portion and an outer portion of the opening, and
wherein widths of at least two of the first to third routing patterns are different from each other.

6. The flexible circuit board of claim 5, wherein a width of a routing wire of the first routing pattern is greater than a width of a routing wire of each of the second routing pattern and the third routing pattern.

7. The flexible circuit board of claim 1, wherein the routing pattern includes first to third routing patterns spaced apart from each other, and
wherein routing wires of the first to third routing patterns have different widths.

8. A Chip On Film (COF) module comprising:
a flexible circuit board according to claim 1; and
a chip disposed in the opening, and
wherein the chip is connected to the routing pads.

9. The COF module of claim 8, wherein a width of the routing wire is greater than or equal to a distance between the routing wire and a terminal part of the chip, and
wherein the width of the routing wire is less than or equal to a length of the terminal part.

10. An electronic device comprising:
a COF module according to claim 9;
a printed circuit board connected to one end of the COF module; and
a display panel connected to another end of COF module the second circuit pattern.

11. The flexible circuit board of claim 7, wherein among the routing wires of the first to third routing patterns, a width of a routing wire located closest to an inner wall of the opening is the smallest, and a width of a routing wire located farthest from the inner wall of the opening is the largest.
